(19) United States
(12) Patent Application Publication
(10) Pub. No.: US 2025/0063665 A1
(43) Pub. Date: Feb. 20, 2025

(54) CIRCUIT BOARD AND METHOD FOR MANUFACTURING MOUNTING BOARD

(71) Applicant: TDK Corporation, Tokyo (JP)

(72) Inventors: Yukari WADA, Tokyo (JP); Akiko SEKI, Tokyo (JP); Yuhei HOTTA, Tokyo (JP); Atsushi SATO, Tokyo (JP)

(73) Assignee: TDK Corporation, Tokyo (JP)

(21) Appl. No.: 18/937,697

(22) Filed: Nov. 5, 2024

Related U.S. Application Data
(63) Continuation of application No. PCT/JP2023/017600, filed on May 10, 2023.

(30) Foreign Application Priority Data
May 18, 2022 (JP) 2022-081600

(51) Int. Cl. H05K 1/18; H05K 3/34

(52) U.S. Cl. CPC H05K 1/183; H05K 1/181; H05K 3/341; H05K 2201/0317; H05K 2201/10106; H05K 2201/10909; H05K 2203/043

(57) ABSTRACT

A circuit board includes: a substrate; at least a pair of terminals provided on the substrate; a bonding material disposed on the terminals and containing a metal element; and a wall of an insulating material disposed on the substrate, in which the pair of terminals and the bonding material are disposed inside the wall, and at least one wall-frame portion of the wall has at least one groove portion passing through an outer peripheral surface from an inner peripheral surface.

### CROSS-REFERENCE TO RELATED APPLICATIONS

This application is a continuation application of PCT Application No. PCT/JP2023/017600, filed on May 10, 2023, which claims the benefit of priority from Japanese Patent Application No. 2022-081600, filed on May 18, 2022. The entire contents of the above listed PCT and priority applications are incorporated herein by reference.

### BACKGROUND

### Field

The present disclosure relates to a circuit board and a method for manufacturing a mounting board.

### Description of the Related Art

In recent years, digitalization has progressed, and along with this, the development of a technique for mounting electronic components on substrates is progressing. For example, a technique for mounting a large number of bare chips of semiconductor light emitting elements represented by light emitting diodes (hereinafter, referred to as “LEDs”) used for lighting, display devices, and the like on a wiring substrate has been developed. For example, Japanese Unexamined Patent Publication No. 2006-93523 discloses an invention in which a semiconductor light emitting element is inserted and bonded into a cavity in which a plurality of semiconductor light emitting elements can be easily positioned and arranged. Furthermore, Japanese Unexamined Patent Publication No. 2004-47772 has also developed a technique for suppressing bringing-back of a semiconductor light emitting element and solder bridging in electronic component mounting using a paste-like bonding material.

### SUMMARY

A circuit board according to the present disclosure is a circuit board including: a substrate; at least a pair of terminals provided on the substrate; a bonding material disposed on the terminals and containing a metal element; and a wall of an insulating material disposed on the substrate, in which the pair of terminals and the bonding material are disposed inside the wall, and at least one wall-frame portion of the wall has at least one groove portion passing through an outer peripheral surface from an inner peripheral surface.

### BRIEF DESCRIPTION OF THE DRAWINGS

FIG. 1 is a schematic cross-sectional view illustrating a mounting board including a circuit board according to an embodiment of the present disclosure.

FIG. 2 is a schematic cross-sectional view illustrating a circuit board according to an embodiment of the present disclosure.

FIG. 3 is a plan view of the circuit board.

FIG. 4A is a view of a wall-frame portion 13C viewed in a Y-axis direction which is a thickness direction, and FIG. 4B is a view of the wall-frame portion 13C viewed in a Z-axis direction.

FIG. 5 is a view illustrating a groove portion of a circuit board according to a modification.

FIGS. 6A and 6B are views illustrating a groove portion of a circuit board according to a modification.

FIGS. 7A and 7B are views illustrating a groove portion of a circuit board according to a modification.

FIG. 8 is a view illustrating a circuit board according to a modification.

FIGS. 9A, 9B, and 9C are schematic cross-sectional views illustrating a method for manufacturing a circuit board and a mounting board.

FIG. 10 is a schematic cross-sectional view illustrating the method for manufacturing a circuit board and a mounting board.

FIGS. 11A, 11B, 11C, 11D, 11E, and 11F are schematic cross-sectional views illustrating a method for manufacturing a wall portion.

FIG. 12 is a schematic cross-sectional view illustrating a circuit board according to a comparative example.

FIG. 13 is a table showing conditions and test results of examples.

FIG. 14 is a table showing conditions and test results of examples.

### DETAILED DESCRIPTION

In the following description, with reference to the drawings, the same reference numbers are assigned to the same components or to similar components having the same function, and overlapping description is omitted.

It is to be understood that not all aspects, advantages and features described herein may necessarily be achieved by, or included in, any one particular example. Indeed, having described and illustrated various examples herein, it should be apparent that other examples may be modified in arrangement and detail.

Here, in a circuit board, a terminal and a bonding material may be disposed inside a wall of an insulating material. For such a circuit board, a filling material may be filled in a wall, an electronic component may be mounted using a holding member, and the electronic component may be bonded to the circuit board by pressing and heating the electronic component into the wall using a pressurization reflow device. At this time, since the excessive filling material stays in the wall and in the upper part of the wall around the electronic component, the electronic component cannot be sufficiently pushed in a pressurizing step using a pressurization reflow device, and there is a possibility that a connection failure occurs between the bonding material of the circuit board and the electronic component.

An object of the present disclosure is to provide a circuit board capable of suppressing a connection failure between a bonding material of the circuit board and an electronic component, and a method for manufacturing a mounting structure.

In the circuit board according to the present disclosure, the pair of terminals and the bonding material are disposed inside the wall. Here, at least one wall-frame portion of the wall has at least one groove portion passing through an outer peripheral surface from an inner peripheral surface. In this case, when the electronic component is mounted on the circuit board by disposing the filling material in the wall, mounting the electronic component using a holding member, and pressing and heating the electronic component into the wall using a pressurization reflow device to bond the electronic component to the circuit board, the excessive filling material can be discharged to the outside of the wall through the groove portion. As a result, the electronic component can be sufficiently pushed into the wall in the pressurizing step using the pressurization reflow device and brought into contact with the bonding material. As described above, a connection failure between the bonding material of the circuit board and the electronic component can be suppressed.

The groove portion may extend from a distal end portion of the wall-frame portion in the height direction orthogonal to a main surface of the substrate toward the substrate side as viewed in a thickness direction of the wall-frame portion, and a bottom surface of the groove portion may be disposed at a position separated from the substrate. In this case, the range of the groove portion can be limited to a part in the height direction. Therefore, it is possible to suppress the filling material from being discharged more than necessary. Furthermore, the strength of the wall-frame portion can be secured.

When an occupied area of the wall-frame portion as viewed in the thickness direction of the wall-frame portion is designated as S, an opening area of the groove portion is designated as Sc, a width of the wall-frame portion in a width direction orthogonal to the thickness direction and the height direction is designated as W, and a length of the wall-frame portion in the thickness direction is designated as L, the following Formulas (1) and (2) may be established. When Formula (1) is satisfied, it is possible to suppress that the filling material becomes difficult to flow due to a too small ratio of the opening area, and it is possible to suppress that a necessary amount of the filling material flows out due to a too large ratio of the opening area. Furthermore, when Formula (2) is satisfied, it is possible to suppress that the width W is narrowed with respect to the length L that is the flow path length, the pressure loss is increased, and the filling material becomes difficult to flow, and it is possible to suppress that a necessary amount of the filling material flows out due to the width W being too wide.

$$[ Math . 1 ]$$

$$0.015 < \frac{{S}_{c}}{S} < 0.75 \qquad ( 1 )$$

$$0.1 ≦ \sum \frac{{W}_{n}}{{L}_{n}} < 12.6 \qquad ( 2 )$$

The groove portion may extend from the distal end portion of the wall-frame portion in the height direction toward the substrate side as viewed in the thickness direction of the wall-frame portion, and the width of the groove portion in the width direction orthogonal to the thickness direction and the height direction may be larger on the distal end portion side than on the bottom surface side. In this case, the channel resistance increases by narrowing the groove portion on the substrate side, and the necessary filling material is held, and the excessive filling material is easily discharged by widening the groove portion on the distal end portion side.

The width of the groove portion in the width direction orthogonal to the thickness direction and the height direction may be larger on an inner peripheral side than on an outer peripheral side as viewed in the height direction. When the width of the groove portion on the inner peripheral side increases, the excessive filling material easily enters the groove portion, but when the width of the groove portion on the outer peripheral side decreases, pressure loss occurs, and the filling material can be suppressed from flowing out more than necessary.

A recess recessed toward an outer peripheral side from an inner peripheral surface of the wall-frame portion may be located at a corner portion where a pair of the wall-frame portions are connected to each other as viewed in the height direction. In this case, it is possible to increase a region where the excessive filling material can flow at the corner portion without dividing the wall-frame portions.

An edge portion of the groove portion may be rounded. In this case, the filling material can smoothly flow through the groove portion.

A dimension of a short side of an inner peripheral surface inside the wall may be 8 μm or more, and a dimension of a long side of the inner peripheral surface may be 68 μm or less. In this case, the size of the wall on the inner peripheral side can be set to an appropriate size.

A method for manufacturing a mounting board according to the present disclosure is a method for manufacturing a mounting board by mounting an electronic component on the above-described circuit board to manufacture a mounting board, in which a filling material is disposed on the substrate, the electronic component is disposed, and then the electronic component may be bonded to the terminal by using a pressurization reflow device.

In this case, the same functions and effects as those of the above-described circuit board can be obtained.

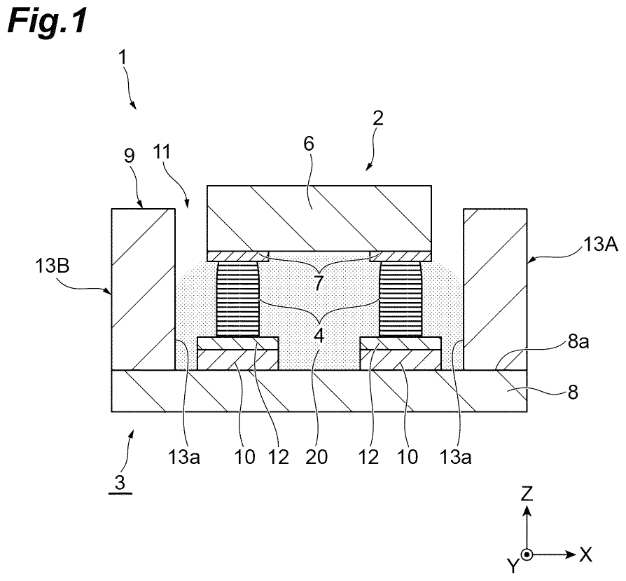

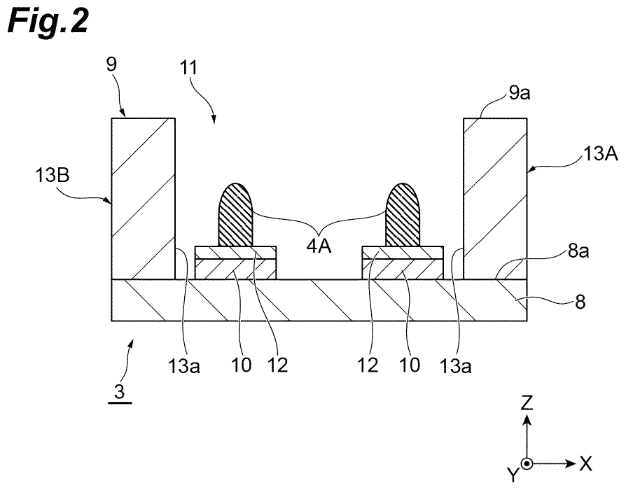

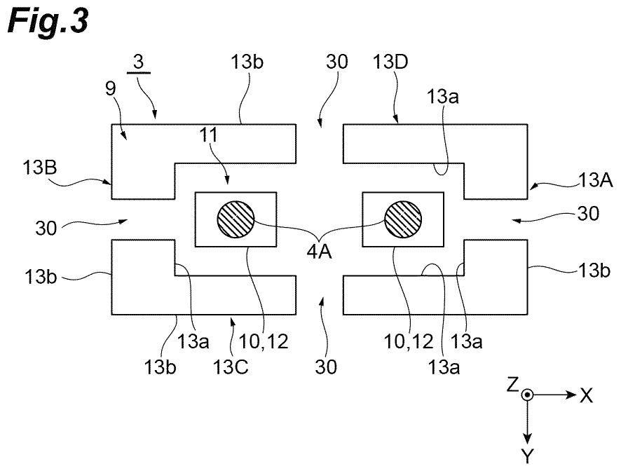

Referring to FIGS. 1 to 3, a circuit board 3 according to an embodiment of the present disclosure will be described. FIG. 1 is a schematic cross-sectional view illustrating a mounting board 1 including the circuit board 3 according to an embodiment of the present disclosure. FIG. 2 is a schematic cross-sectional view illustrating the circuit board 3 according to an embodiment of the present disclosure. FIG. 3 is a plan view of the circuit board 3.

As illustrated in FIG. 1, the mounting board 1 includes an electronic component 2 and the circuit board 3. The mounting board 1 is configured by mounting the electronic component 2 on the circuit board 3 via a bonding material 4.

The electronic component 2 includes a body portion 6 and a pair of terminals 7. The body portion 6 is a member for exhibiting a function as the electronic component 2. The terminals 7 are metal portions formed on a main surface of the body portion 6. As a material for the terminals 7, a metal such as Cu, Ti, Au, Ni, Sn, Bi, P, B, In, Ag, Zn, Pd, Mo, Pt, Cr, and an alloy selected from at least two of them, or the like is adopted. The electronic component 2 is configured of, for example, a micro LED, or the like. The micro LED is a component emitting light according to an input from the circuit board 3.

The circuit board 3 includes a substrate 8, a wall 9, and a pair of terminals 10. The substrate 8 is a flat plate-shaped body portion of the circuit board 3. The substrate 8 has a main surface 8a. Note that the following description may be made using XYZ coordinates set for the circuit board 3. An X-axis direction is a direction parallel to the main surface 8a of the substrate 8, a Y-axis direction is a direction parallel to the main surface 8a of the substrate 8 and orthogonal to the X-axis direction, and a Z-axis direction (height direction) is a direction orthogonal to the main surface 8a of the substrate 8.

The wall 9 is a member formed of an insulating material formed on the main surface 8a of the substrate 8. The mounting board 1 has the wall 9 of the insulating material disposed on the substrate. The wall 9 rises from the substrate 8 toward the positive side in the Z-axis direction. As illustrated in FIG. 3, in the present embodiment, the wall 9 has wall-frame portions 13A, 13B, 13C, and 13D provided in four directions. The wall-frame portions 13A and 13B face each other in a state of being separated from each other in the X-axis direction, and extend in parallel to the Y-axis direction. The wall-frame portion 13A is disposed on the positive side in the X-axis direction, and the wall-frame portion 13B is disposed on the negative side. The wall-frame portions 13C and 13D face each other in a state of being separated from each other in the Y-axis direction, and extend in parallel to the X-axis direction. The wall-frame portion 13C is disposed on the positive side in the Y-axis direction, and the wall-frame portion 13D is disposed on the negative side. The wall-frame portion 13A connects end portions of the wall-frame portions 13C and 13D on the positive side in the X-axis direction to each other. The wall-frame portion 13B connects the end portions of the wall-frame portions 13C and 13D on the negative side in the X-axis direction to each other. As a result, the wall 9 has a rectangular frame-shaped structure as viewed in the Z-axis direction. The wall-frame portions 13A and 13B constitute short sides, and the wall-frame portions 13C and 13D constitute long sides. Note that, the dimension is not particularly limited, but the dimension in the Y-axis direction of the wall-frame portions 13A and 13B may be set to 10 to 60 μm. The dimension in the X-axis direction of the wall-frame portions 13C and 13D may be set to 15 to 70 μm. The dimension of the short side of the inner peripheral surface inside the wall 9 may be set to 8 μm or more and 44 μm or less. The dimension of the long side of the inner peripheral surface inside the wall 9 may be 15 μm or more and 68 μm or less. The dimension of the short side of the inner peripheral surface inside the wall 9 is the dimension in the Y-axis direction of an inner peripheral surface 13a of the wall-frame portion 13C and an inner peripheral surface 13a of the wall-frame portion 13D. The dimension of the long side of the inner peripheral surface inside the wall 9 is the dimension in the X-axis direction of an inner peripheral surface 13a of the wall-frame portion 13A and an inner peripheral surface 13a of the wall-frame portion 13B. As a material for the wall 9, for example, a resin material such as an epoxy resin, an acrylic resin, a phenol resin, a melamine resin, a urea resin, or an alkyd resin is adopted. Particularly preferably, as a material for the wall 9, an epoxy resin or an acrylic resin is adopted.

As illustrated in FIGS. 1 to 3, the terminals 10 are metal portions formed on the main surface 8a of the substrate 8. As a material for the terminals 10, Ni, Cu, Ti, Cr, Al, Mo, Pt, Au, an alloy selected from at least two of them, or the like is adopted. A conductive film 12 is formed on an upper surface of the terminal 10. As a material for the conductive film 12, a film of Ti, Cu, Ni, Al, Mo, Cr, Ag, or the like, a film in which metal particles and a binder are mixed, or the like is adopted.

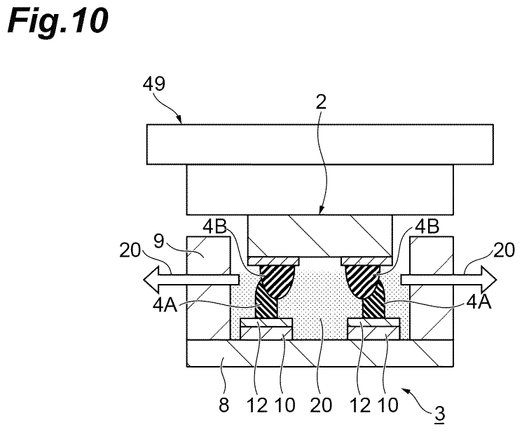

The bonding material 4 is a member bonding the terminals 7 of the electronic component 2 and the terminals 10 of the circuit board 3. The bonding material 4 is configured by thermally bonding and integrating a bonding material 4A on the circuit board 3 side and a bonding material 4B on the electronic component 2 side (see FIG. 10(b)). The bonding material 4 may contain Sn or may be made of an alloy containing Sn. However, the bonding material 4 is not necessarily limited to one containing Sn. The bonding material 4 may be made of an alloy containing, in addition to Sn, an element lowering a melting point of Sn. Examples of the element lowering a melting point of Sn include Bi. The bonding material 4 functions as solder. Thus, the terminals 10, the conductive film 12, the bonding material 4, and the terminals 7 are stacked in this order from the upper surface of the substrate 8 between the substrate 8 and the body portion 6. Note that, solder bonding is performed at that location after the terminals 10, the conductive film 12, the bonding material 4, and the terminals 7 are stacked. Therefore, a structure in which the metals of the terminals 10, the conductive film 12, the bonding material 4, and the terminals 7 are melted and diffused is formed. The structure after such solder bonding may be a structure containing a brittle intermetallic compound (IMC). When an intermetallic compound having a brittle structure is present, it is likely to be fractured due to stress from the outside, and thus reliability tends to decrease. Therefore, the effect of protecting the electronic component 2 is achieved by surrounding the electronic component 2 with the wall 9.

A recess 11 is formed in the wall 9. The recess 11 is configured by a through hole passing through the wall 9 in the Z-axis direction. Thus, the upper surface of the substrate 8 is exposed on the bottom side of the recess 11. The recess 11 has a rectangular shape as viewed in the Z-axis direction (see FIG. 3). The terminals 7, the terminals 10, the conductive film 12, and the bonding material 4 are disposed in the recess 11 formed in the wall 9 so as to be surrounded by the wall 9. Slight gaps are formed between the inner peripheral surfaces 13a of the four wall-frame portions 13A, 13B, 13C, and 13D constituting the recess 11 and the terminals 7, the terminals 10, the conductive film 12, and the bonding material 4.

A filling material 20 is disposed between the electronic component 2 and the bonding material 4, and the wall 9 in the recess 11. Thus, the electronic component 2 can be made difficult to be separated from the circuit board 3 by being supported by the filling material 20. Furthermore, a force applied to the electronic component 2, the bonding material 4, and the terminals 7 and 10 is relaxed, and reliability can be improved. As a material for the filling material 20, for example, an epoxy resin, an acrylic resin, a phenol resin, a melamine resin, a urea resin, an alkyd resin, a mixture thereof, or a mixture of the above-described resin materials with SiOx, ceramics, and the like is adopted. Particularly preferably, as a material for the filling material 20, an epoxy resin or an acrylic resin is adopted. A viscosity of the filling material 20 at the time of filling may be 1 to 20 Pa and may be further 5 to 10 Pa.

As illustrated in FIG. 2, the circuit board 3 has a configuration in which the electronic component 2 and the filling material 20 are removed from the mounting board 1 illustrated in FIG. 1. Note that, in the circuit board 3, the bonding material 4A containing a metal element is disposed above the terminals 10 (on the upper surface of the conductive film 12). As described above, the bonding material 4A constitutes a part of the bonding material 4 in the previous stage in which the electronic component 2 and the mounting board 1 are thermally bonded. In the state of the circuit board 3, the pair of terminals 10, the conductive film 12, and the bonding material 4A are disposed inside the wall 9 formed of an insulating material.

As illustrated in FIG. 3, at least one groove portion 30 passing through an outer peripheral surface 13b from the inner peripheral surface 13a is formed in the wall-frame portions 13A, 13B, 13C, and 13D. The wall-frame portions 13A, 13B, 13C, and 13D have at least one groove portion 30 passing through the outer peripheral surface 13b from the inner peripheral surface 13a. Note that, for the wall-frame portions 13A and 13B, the X-axis direction is the thickness direction. Therefore, the groove portion 30 of the wall-frame portions 13A and 13B extends in the X-axis direction and passes through the wall-frame portions 13A and 13B. For the wall-frame portions 13C and 13D, the Y-axis direction is the thickness direction. Therefore, the groove portion 30 of the wall-frame portions 13C and 13D extends in the Y-axis direction and passes through the wall-frame portions 13C and 13D. Note that, the groove portion 30 may be formed in at least one of the wall-frame portions 13A, 13B, 13C, and 13D. Furthermore, a plurality of groove portions 30 may be formed in the wall-frame portions 13A, 13B, 13C, and 13D.

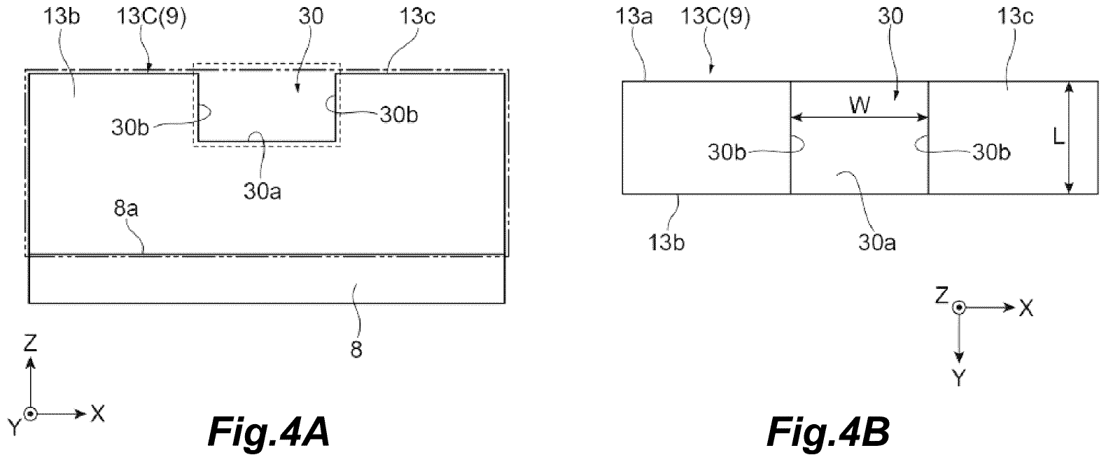

Next, referring to FIGS. 4A and 4B, a configuration of the wall-frame portion 13C as viewed in the thickness direction will be described. FIG. 4A is a view of the wall-frame portion 13C as viewed in the Y-axis direction which is the thickness direction. FIG. 4B is a view of the wall-frame portion 13C as viewed in the Z-axis direction. Note that, although the wall-frame portion 13C is illustrated in FIG. 4, the same description holds for the other wall-frame portions 13A, 13B, and 13D. As illustrated in FIG. 4A, as viewed in the Y-axis direction which is the thickness direction of the wall-frame portion 13C, the groove portion 30 extends from a distal end portion 13c in the Z-axis direction of the wall-frame portion 13C toward the substrate 8 side (the negative side in the Z-axis direction). The groove portion 30 has a bottom surface 30a and a pair of side surfaces 30b. The bottom surface 30a is formed on the negative side in the Z-axis direction with respect to the distal end portion 13c. The pair of side surfaces 30b extends from both end portions of the bottom surface 30a in the X-axis direction to the distal end portion 13c. In an example illustrated in FIG. 4A, the bottom surface 30a of the groove portion 30 is disposed at a position separated from the substrate 8. The member of the wall-frame portion 13C exists between the bottom surface 30a and the main surface 8a of the substrate 8.

An occupied area of the wall-frame portion 13C as viewed in the Y-axis direction, which is the thickness direction of the wall-frame portion 13C, is designated as S. The occupied area S is an area of the wall-frame portion 13C when it is assumed that the groove portion 30 is not formed, and corresponds to an area of a portion surrounded by a two-dot chain line in FIG. 4A. An opening area of the groove portion 30 is designated as Sc. The opening area Sc is an area corresponding to the bottom surface 30a, the pair of side surfaces 30b, and the imaginary distal end portion 13c, and corresponds to an area of a portion surrounded by a broken line in FIG. 4A. As illustrated in FIG. 4B, a width of the wall-frame portion 13C in the X-axis direction (width direction) is designated as W. A length of the wall-frame portion 13C in the Y-axis direction, which is the thickness direction, is designated as L.

At this time, the following Formulas (1) and (2) are established. Note that, the dimension range of the width W is not particularly limited, and may be set to, for example, a range of 3 to 16 μm. The length L is not particularly limited, and may be set to, for example, a range of 5 to 20 μm. Note that, Formula (2) indicates the sum of “W/L” when n groove portions 30 are present in one wall-frame portion 13. Furthermore, the opening area Sc is the sum of the opening areas of the n groove portions 30.

$$[ Math . 2 ]$$

$$0.015 < \frac{{S}_{c}}{S} < 0.75 \qquad ( 1 )$$

$$0.1 ≦ \sum \frac{{W}_{n}}{{L}_{n}} < 12.6 \qquad ( 2 )$$

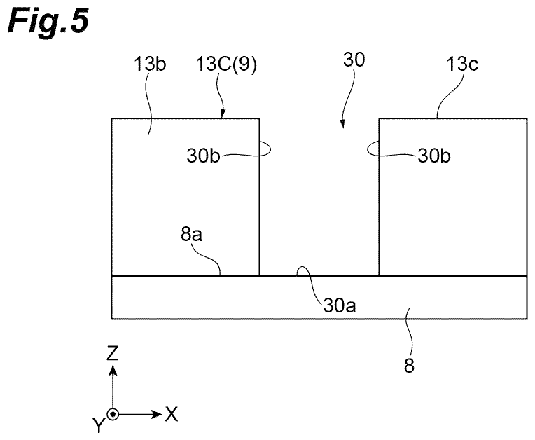

As illustrated in FIG. 5, the groove portion 30 may extend to the main surface 8a of the substrate 8. In this case, the main surface 8a of the substrate 8 forms the bottom surface 30a of the groove portion 30. In this configuration, a region on the negative side in the X-axis direction and a region on the positive side in the X-axis direction of the wall-frame portion 13C are divided by the groove portion 30.

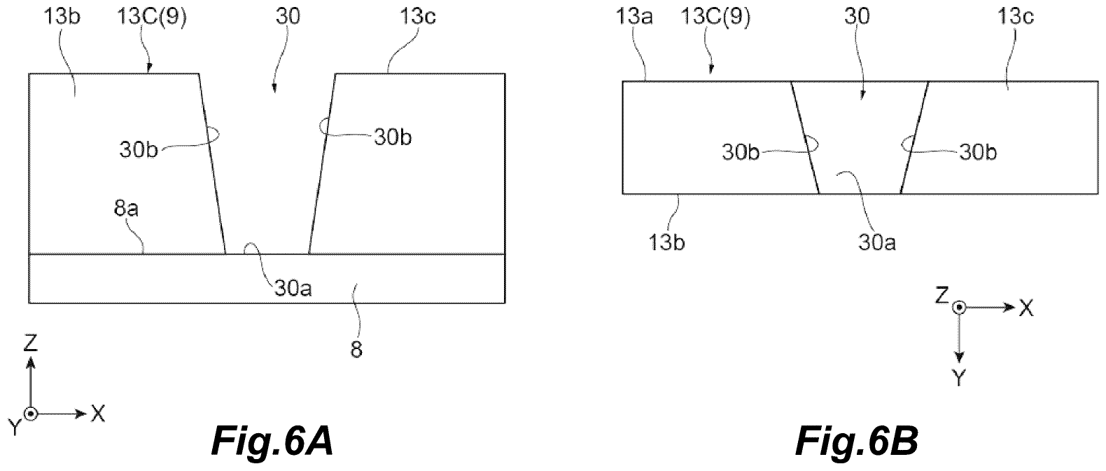

As illustrated in FIG. 6A, the width of the groove portion 30 in the X-axis direction, which is the width direction, is larger on the distal end portion 13c side than on the bottom surface 30a side. The width of the groove portion 30 at the distal end portion 13c is larger than the width of the groove portion 30 at the bottom surface 30a. In an example illustrated in FIG. 6A, the groove portion 30 is largely opened in the X-axis direction toward the distal end portion 13c side. The pair of side surfaces 30b is inclined such that a distance between the side surfaces increases toward the positive side in the Z-axis direction.

As illustrated in FIG. 6B, the width of the groove portion 30 in the X-axis direction, which is the width direction is larger on an inner peripheral side than on an outer peripheral side as viewed in the Z-axis direction which is the height direction. The width of the groove portion 30 in the inner peripheral surface 13a is larger than the width of the groove portion 30 in the outer peripheral surface 13b. In an example illustrated in FIG. 6B, the groove portion 30 is largely opened in the X-axis direction toward the inner peripheral surface 13a side. The pair of side surfaces 30b is inclined such that a distance between the side surfaces increases toward the negative side in the Y-axis direction which is the inner peripheral side.

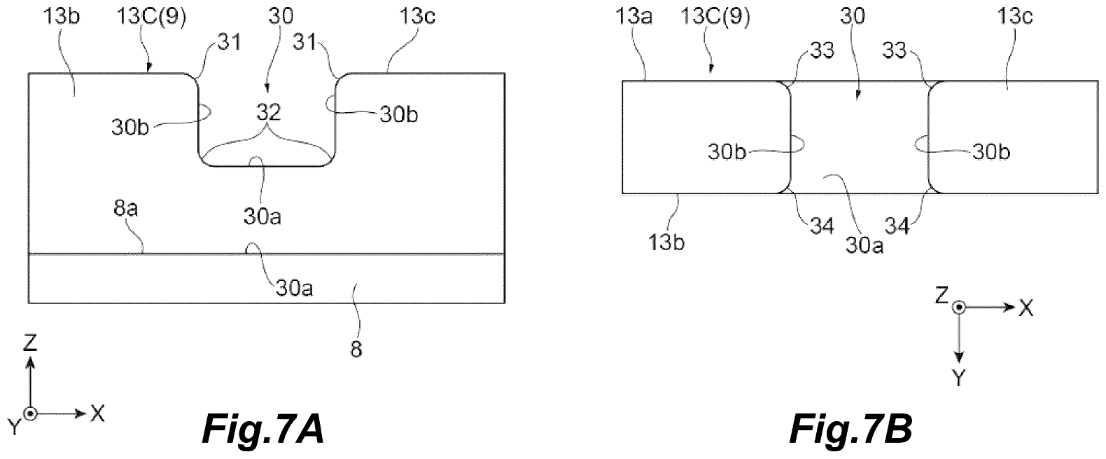

As illustrated in FIG. 7, an edge portion of the groove portion 30 is rounded (corner radius R). As illustrated in FIG. 7A, an edge portion 31 between the distal end portion 13c and the side surface 30b is rounded. An edge portion 32 between the bottom surface 30a and the side surface 30b is rounded. As illustrated in FIG. 7B, an edge portion 33 between the inner peripheral surface 13a and the side surface 30b is rounded. An edge portion 34 between the outer peripheral surface 13b and the side surface 30b is rounded.

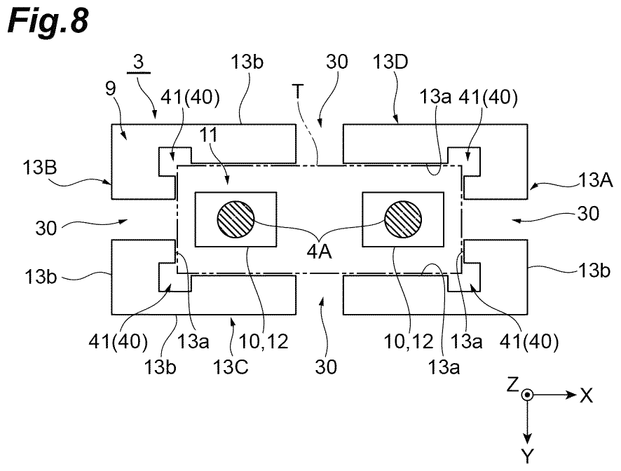

As illustrated in FIG. 8, a recess 41 recessed toward an outer peripheral side from the inner peripheral surface 13a of the wall-frame portion is formed at a corner portion 40 where a pair of the wall-frame portions are connected to each other as viewed in the Z-axis direction which is the height direction. The recess 41 is located at a corner portion 40 as viewed in the Z-axis direction. For example, a rectangle T having a minimum area circumscribing the inner peripheral surface 13a of the wall-frame portion is set. At this time, in the four corner portions 40, the recess 41 can increase the area of the rectangle T. The recess 41 has a quadrangular shape as viewed in the Z-axis direction, but may have another polygonal shape or a circular shape.

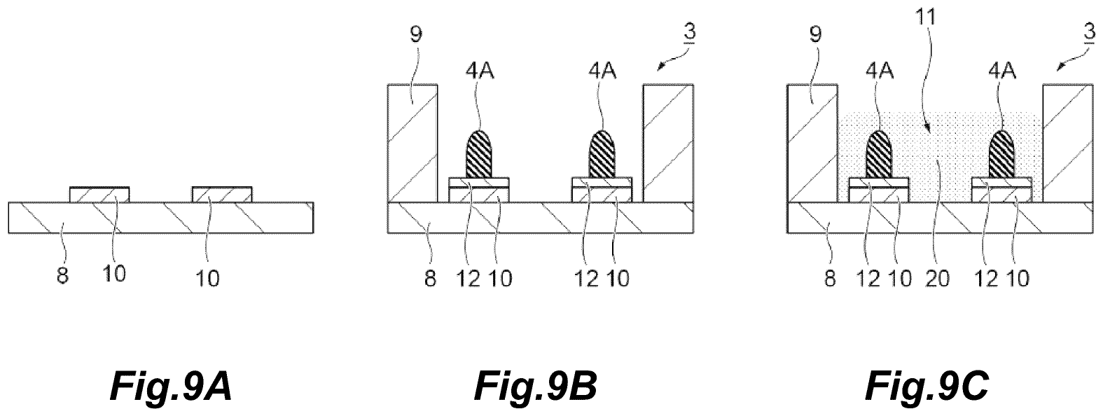

Referring to FIGS. 9A to 9C and 10, a method for manufacturing the circuit board 3 and the mounting board 1 will be described. First, as illustrated in FIG. 9A, the terminals 10 are formed on the upper surface of the substrate 8. Next, as illustrated in FIG. 9B, the conductive film 12 and the bonding material 4 are formed on the upper surface of the terminals 10, and the wall 9 is formed on the substrate 8. Thus, the circuit board 3 is completed. Next, as illustrated in FIG. 9C, the filling material 20 is disposed on the substrate 8 by filling the recess 11 with the filling material 20. Then, the electronic component 2 is held by a holding member, and the electronic component 2 is mounted in the recess 11. Next, as illustrated in FIG. 10, the electronic component 2 is pressed into the recess 11 by a pressurization reflow device 49 with respect to the electronic component 2, and the bonding material 4A and the bonding material 4B are brought into contact with each other inside the filling material 20. At this time, a part of the filling material 20 flows out of the wall 9 from the groove portion 30 (see FIG. 3). Next, the bonding material 4B of the electronic component 2 and the bonding material 4A of the substrate 8 are bonded by heating. Thus, the mounting board 1 is completed.

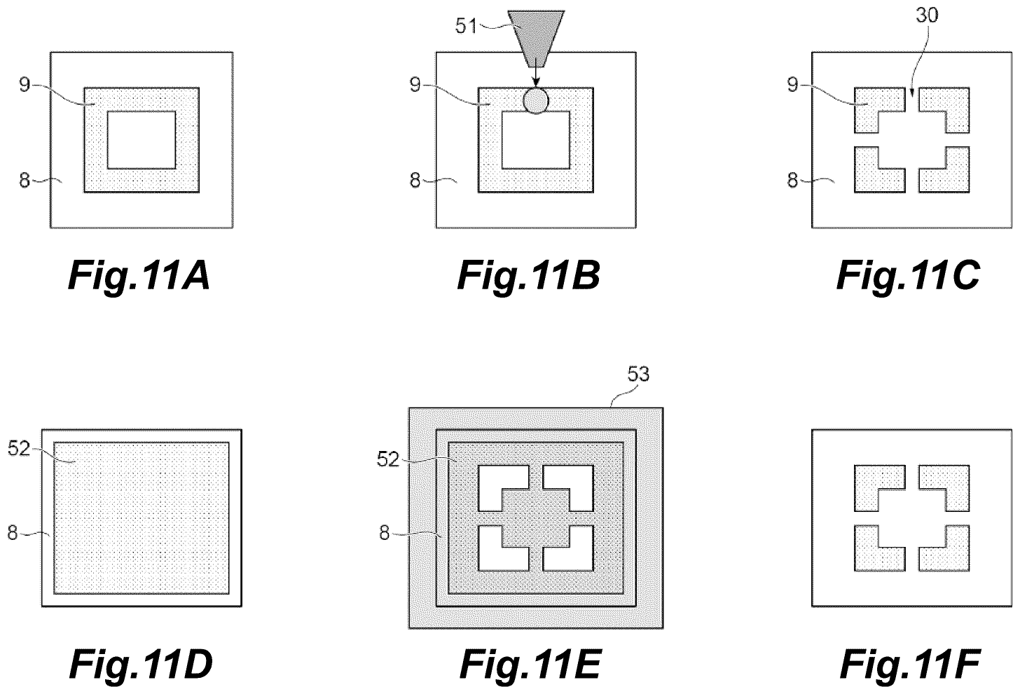

Next, referring to FIGS. 11A to 11F, a method of forming the wall 9 having the groove portion 30 will be described. First, as illustrated in FIG. 11A, the wall 9 is formed on the substrate 8. Next, as illustrated in FIG. 11B, a part of the wall 9 is processed by irradiating the wall 9 with a laser beam by a laser device 51. As a result, as illustrated in FIG. 11C, the groove portion 30 is formed in the wall 9.

Alternatively, as illustrated in FIG. 11D, a resist 52 is formed on the substrate 8. Next, as illustrated in FIG. 11E, exposure is performed using a glass mask 53 having a pattern corresponding to the shape of the wall 9 having the groove portion 30. As illustrated in FIG. 11F, the exposed resist 52 is developed to form the wall 9 having the groove portion 30.

Next, functions and effects of the circuit board 3 and the method for manufacturing the mounting board 1 according to the present embodiment will be described.

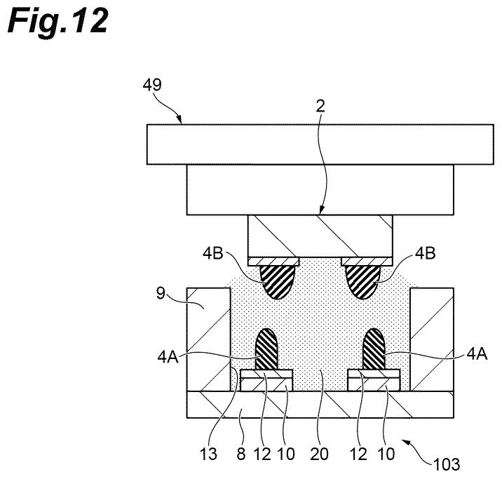

First, a circuit board 103 according to a comparative example will be described with reference to FIG. 12. The wall 9 of the circuit board 103 does not have the groove portion 30 described above. After the filling material 20 is filled in the wall 9, when the electronic component 2 is mounted in the wall 9 using a holding member and the electronic component 2 is pushed by a pressurization reflow device, the electronic component 2 cannot be sufficiently pushed due to the influence of the excessive filling material 20. In this case, reflow is performed in a state where the bonding material 4B of the electronic component 2 and the bonding material 4A of the circuit board 3 remain separated from each other, and there is a possibility that a connection failure occurs between the bonding material 4A of the circuit board 3 and the electronic component 2.

On the other hand, in the circuit board 3 according to the present embodiment, the pair of terminals 10 and the bonding material 4A are disposed in the wall 9. Here, at least one groove portion 30 passing through the outer peripheral surface 13b from the inner peripheral surface 13a is formed in at least one wall-frame portion 13 of the wall 9. At least one of wall-frame portion 13 of the wall 9 has at least one groove portion 30 passing through the outer peripheral surface 13b from the inner peripheral surface 13a. In this case, when the electronic component 2 is mounted on the circuit board 3 by disposing the filling material 20 in the wall 9, mounting the electronic component using a holding member, and pressing and heating the electronic component 2 into the wall 9 using the pressurization reflow device 49 to bond the electronic component 2 to the circuit board 3, the excessive filling material 20 can be discharged to the outside of the wall 9 through the groove portion 30. As a result, the electronic component 2 can be sufficiently pushed into the wall 9 in the pressurizing step using the pressurization reflow device 49 and brought into contact with the bonding material 4A. As described above, a connection failure between the bonding material 4A of the circuit board 3 and the electronic component 2 can be suppressed.

The groove portion 30 may extend from the distal end portion 13c of the wall-frame portion 13 in the height direction toward the substrate 8 side as viewed in a thickness direction of the wall-frame portion 13, and the bottom surface 30a of the groove portion 30 may be disposed at a position separated from the substrate 8. In this case, the range of the groove portion 30 can be limited to a part in the height direction. Therefore, it is possible to suppress the filling material 20 from being discharged more than necessary. Furthermore, the strength of the wall-frame portion 13 can be secured.

When an occupied area of the wall-frame portion 13 as viewed in the thickness direction of the wall-frame portion 13 is designated as S, an opening area of the groove portion 30 is designated as Sc, a width of the wall-frame portion 13 in a width direction orthogonal to the thickness direction and the height direction is designated as W, and a length of the wall-frame portion 13 in the thickness direction is designated as L, the following Formulas (1) and (2) may be established. When Formula (1) is satisfied, it is possible to suppress that the filling material 20 becomes difficult to flow due to a too small ratio of the opening area, and it is possible to suppress that a necessary amount of the filling material 20 flows out due to a too large ratio of the opening area. Furthermore, when Formula (2) is satisfied, it is possible to suppress that the width W is narrowed with respect to the length L that is the flow path length, the pressure loss is increased, and the filling material 20 becomes difficult to flow, and it is possible to suppress that a necessary amount of the filling material flows out due to the width W being too wide.

$$[ Math . 3 ]$$

$$0.015 < \frac{{S}_{c}}{S} < 0.75 \qquad ( 1 )$$

$$0.1 ≦ \sum \frac{{W}_{n}}{{L}_{n}} < 12.6 \qquad ( 2 )$$

The groove portion 30 may extend from the distal end portion 13c of the wall-frame portion 13 in the height direction toward the substrate 8 side as viewed in the thickness direction of the wall-frame portion 13, and the width of the groove portion 30 in the width direction orthogonal to the thickness direction and the height direction may be larger on the distal end portion 13c side than on the bottom surface 30a side. In this case, the channel resistance increases by narrowing the groove portion 30 on the substrate 8 side, and the necessary filling material 20 is held, and the excessive filling material 20 is easily discharged by widening the groove portion 30 on the distal end portion 13c side.

The width of the groove portion 30 in the width direction orthogonal to the thickness direction and the height direction may be larger on the inner peripheral side than on the outer peripheral side as viewed in the height direction. When the width of the groove portion 30 on the inner peripheral side increases, the excessive filling material 20 easily enters the groove portion 30, but when the width of the groove portion 30 on the outer peripheral side decreases, pressure loss occurs, and the filling material 20 can be suppressed from flowing out more than necessary.

The recess 41 recessed toward an outer peripheral side from the inner peripheral surface 13a of the wall-frame portion 13 may be formed at the corner portion 40 where a pair of the wall-frame portions 13 are connected to each other as viewed in the height direction. In this case, it is possible to increase a region where the excessive filling material 20 can flow at the corner portion 40 without dividing the wall-frame portions 13.

The edge portions 31, 32, 33, and 34 of the groove portion 30 may be rounded. In this case, the filling material 20 can smoothly flow through the groove portion 30.

A dimension of a short side of an inner peripheral surface inside the wall 9 may be 8 μm or more, and a dimension of a long side of the inner peripheral surface may be 68 μm or less. In this case, the size of the wall 9 on the inner peripheral side can be set to an appropriate size.

The method for manufacturing the mounting board 1 according to the present embodiment is a method for manufacturing the mounting board 1 by mounting the electronic component 2 on the above-described circuit board 3 to manufacture the mounting board 1, in which the filling material 20 is disposed on the substrate 8, the electronic component 2 is disposed, and then the electronic component 2 may be bonded to the terminal 10 by using the pressurization reflow device 49.

In this case, the same functions and effects as those of the above-described circuit board 3 can be obtained.

The present disclosure is not limited to the embodiments described above. For example, the number and arrangement of terminals of the circuit board are not particularly limited. Furthermore, although one electronic component 2 is disposed in the wall 9 in the above-described embodiment, a plurality of electronic components 2 may be disposed. An arrangement mode of the plurality of electronic components 2 is not particularly limited.

### EXAMPLES

Examples of the mounting board according to the present disclosure will be described. Note that, the present disclosure is not limited to the following Examples.

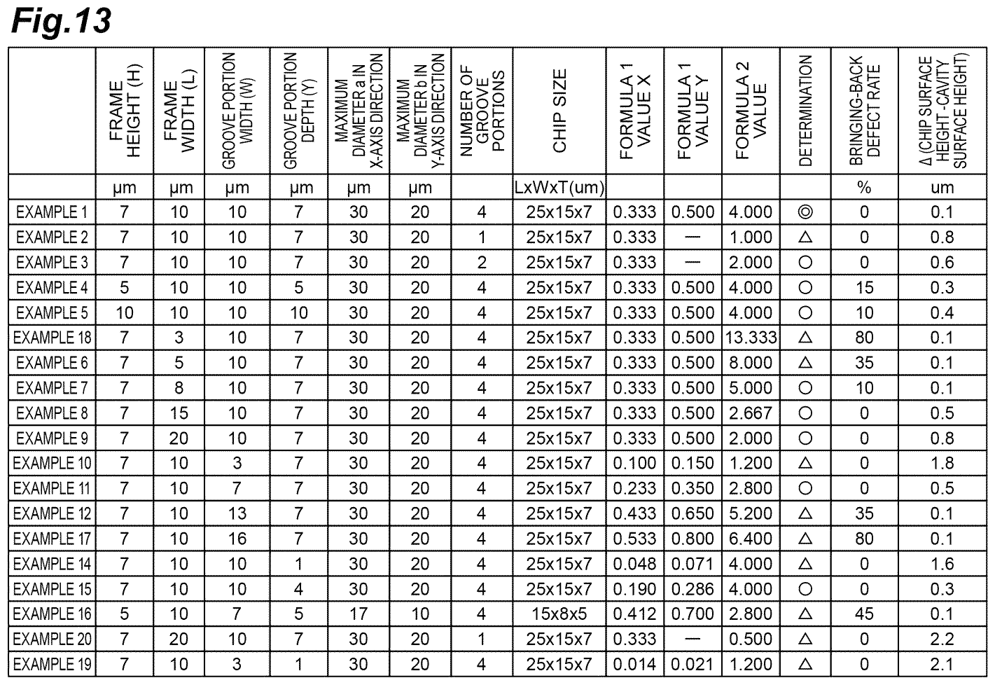

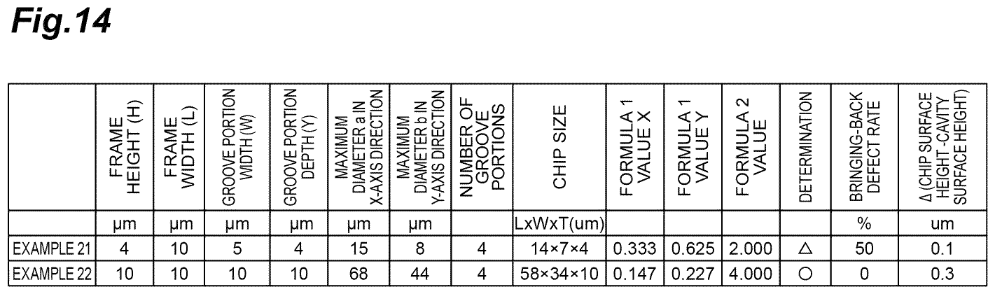

First, mounting boards of Examples 1 to 22 were prepared by the following manufacturing method. First, the circuit board 3 was obtained by forming the wall 9 having the groove portion 30 on the substrate 8 so as to surround the terminals 10 and the bonding material 4. Next, the circuit board 3 was filled with the filling material 20, and an LED chip was mounted as the electronic component 2. Next, the mounting board 1 in this state was pressurized at 0.01 MPa by the pressurization reflow device 49 and reflowed at 150° C. to 190° C. As a result, the circuit board 3 and the electronic component 2 were bonded. Various conditions of Examples 1 to 22 are shown in the tables of FIGS. 13 and 14. Note that, the “frame height (H)” in the tables of FIGS. 13 and 14 is a dimension in the height direction of the wall-frame portion 13. The “frame width (L)” is a dimension in the thickness direction of the wall-frame portion 13 (see FIG. 4B). The “slit width (W)” is the width W of the groove portion 30 (see FIG. 4B). The “groove portion depth (Y)” is a dimension in the height direction of the groove portion. When the “groove portion depth (Y)” and the “frame height (H)” are equal to each other, it means that the groove portion 30 extends to the main surface 8a of the substrate 8. The “maximum diameter a in the X-axis direction” is a dimension of the long side of the inner peripheral surface of the wall 9. The “maximum diameter b in the Y-axis direction” is a dimension of the short side of the inner peripheral surface of the wall 9. The “number of groove portions” is the number of groove portions 30, and the groove portion 30 is formed in each of the four wall-frame portions 13 in the case of “4” and the groove portion 30 is formed only in one of the wall-frame portions on the long side in the case of “1”. The “chip size” is a dimension of the LED chip which is the electronic component 2. The “Formula 1 value X” is a value in the X-axis direction of the above Formula (1). The “Formula 1 value Y” is a value in the Y-axis direction of the above Formula (1). The “Formula 2 value” is a value of the above Formula (2). “Determination” indicates the determination result of evaluation, and the double circle means that the bringing-back defect does not occur and a difference between the chip height and the surface height of the cavity is less than 0.2 μm. The single circle means that the bringing-back defect is less than 30%, and the difference between the chip height and the surface height of the cavity is 0.2 μm or more and less than 1.0 μm. The triangle means that the bringing-back defect is 30% or more, or there is a problem in that, for example, the difference between the chip height and the surface height of the cavity is 1.0 μm or more, or the upper surface of the chip is not mounted parallel to the substrate. The “bringing-back defect rate (%)” indicates a ratio of the mounting board 1 in which a bringing-back defect occurs. When the pressurization reflow device 49 is lifted from the state of FIG. 10, the proportion of the number of electronic components 2 detached from the circuit board 3 and brought back by the pressurization reflow device 49 among 100 mounting boards 1 is the bringing-back defect rate. “A (chip surface height-cavity surface height)” is a value of a gap between the upper surface of the LED chip as the electronic component 2 and the upper surface of the wall 9, and the smaller the value, the better the LED chip can be pushed in.

Note that, in FIGS. 13 and 14, the amount of the filling material 20 was adjusted so that a difference in effect between Examples 1 to 16, 21, and 22 satisfying both Formulas (1) and (2) and Examples 17 to 20 not satisfying at least one of Formulas (1) and (2) can be compared. However, also in Examples 17 to 20, by adjusting the filling material 20, the effect is larger than that of the wall-frame portion 13 in which the groove portion 30 is not formed.

First, in Example 17, since the groove portion width (W) was too large, the filling material 20 flowed from the groove portion 30, so that the LED chip could not be held, and bringing-back defects increased. In Example 18, since the frame width (L) was small, the filling material 20 flowed out of the groove portion 30, so that the LED chip could not be held, and bringing-back defects increased. In Example 19, since the groove portion 30 was narrow and shallow, the filling material 20 hardly flowed from the groove portion 30, and the LED chip was hardly pushed in. In Example 20, since the frame width (L) of the wall-frame portion 13 was large and the number of groove portions 30 was small, the filling material 20 hardly flowed from the groove portion 30, and the LED chip was hardly pushed in.

On the other hand, since Examples 1 to 16, 21, and 22 satisfied both Formulas (1) and (2), bringing-back defects were suppressed, and the LED chip was also pushed well in. The most suitable results were obtained in Example 1. In Example 2, since the number of groove portions 30 was one, the filling material 20 was difficult to flow and appeared to be inclined.

### Embodiment 1

A circuit board including:
a substrate;
at least a pair of terminals provided on the substrate;
a bonding material disposed on the terminals and containing a metal element; and
a wall of an insulating material disposed on the substrate, wherein
the pair of terminals and the bonding material are disposed inside the wall, and
at least one wall-frame portion of the wall has at least one groove portion passing through an outer peripheral surface from an inner peripheral surface.

### Embodiment 2

The circuit board according to embodiment 1, wherein the groove portion extends from a distal end portion of the wall-frame portion in the height direction orthogonal to a main surface of the substrate toward the substrate side as viewed in a thickness direction of the wall-frame portion, and a bottom surface of the groove portion is disposed at a position separated from the substrate.

### Embodiment 3

The circuit board according to embodiment 1 or 2, wherein when an occupied area of the wall-frame portion as viewed in the thickness direction of the wall-frame portion is designated as S, an opening area of the groove portion is designated as Sc, a width of the wall-frame portion in a width direction orthogonal to the thickness direction and the height direction is designated as W, and a length of the wall-frame portion in the thickness direction is designated as L, the following Formulas (1) and (2) are established:

$$[ Math . 4 ]$$

$$0.015 < \frac{{S}_{c}}{S} < 0.75 \qquad ( 1 )$$

$$0.1 ≦ \sum \frac{{W}_{n}}{{L}_{n}} < 12.6 \qquad ( 2 )$$

### Embodiment 4

The circuit board according to any one of embodiments 1 to 3, wherein
the groove portion extends from the distal end portion of the wall-frame portion in the height direction toward the substrate side as viewed in the thickness direction of the wall-frame portion, and
the width of the groove portion in the width direction orthogonal to the thickness direction and the height direction is larger on the distal end portion side than on the bottom surface side.

### Embodiment 5

The circuit board according to any one of embodiments 1 to 4, wherein the width of the groove portion in the width direction orthogonal to the thickness direction and the height direction is larger on an inner peripheral side than on an outer peripheral side as viewed in the height direction.

### Embodiment 6

The circuit board according to any one of embodiments 1 to 5, wherein a recess recessed toward an outer peripheral side from an inner peripheral surface of the wall-frame portion is located at a corner portion where a pair of the wall-frame portions are connected to each other as viewed in the height direction.

### Embodiment 7

The circuit board according to any one of embodiments 1 to 6, wherein an edge portion of the groove portion is rounded.

### Embodiment 8

The circuit board according to any one of embodiments 1 to 7, wherein a dimension of a short side of an inner peripheral surface inside the wall is 8 μm or more, and a dimension of a long side of the inner peripheral surface is 68 μm or less.

### Embodiment 9

A method for manufacturing a mounting board, the method including mounting an electronic component on the circuit board according to any one of embodiments 1 to 8 to manufacture a mounting board, wherein
a filling material is disposed on the substrate, the electronic component is disposed, and then the electronic component is bonded to the terminal by using a pressurization reflow device.

### REFERENCE SIGNS LIST

3 Circuit board
4A Bonding material
8 Substrate
9 Wall
10 Terminal
13A, 13B, 13C, 13D Wall-frame portion
20 Filling material
30 Groove portion
31, 32, 33, 34 Edge portion
40 Corner portion
41 Recess
49 Pressurization reflow device

What is claimed is:

1. A circuit board comprising:
a substrate;
at least a pair of terminals provided on the substrate;
a bonding material disposed on the terminals and containing a metal element; and
a wall of an insulating material disposed on the substrate, wherein
the pair of terminals and the bonding material are disposed inside the wall, and
at least one wall-frame portion of the wall has at least one groove portion passing through an outer peripheral surface from an inner peripheral surface.

2. The circuit board according to claim 1, wherein the groove portion extends from a distal end portion of the wall-frame portion in a height direction orthogonal to a main surface of the substrate toward the substrate side as viewed in a thickness direction of the wall-frame portion, and a bottom surface of the groove portion is disposed at a position separated from the substrate.

3. The circuit board according to claim 1, wherein when an occupied area of the wall-frame portion as viewed in the thickness direction of the wall-frame portion is designated as S, an opening area of the groove portion is designated as Sc, a width of the wall-frame portion in a width direction orthogonal to the thickness direction and the height direction is designated as W, and a length of the wall-frame portion in the thickness direction is designated as L, the following Formulas (1) and (2) are established:
$$[ Math . 1 ]$$
$$0.015 < \frac{{S}_{c}}{S} < 0.75 \qquad ( 1 )$$
$$0.1 ≦ \sum \frac{{W}_{n}}{{L}_{n}} < 12.6 \qquad ( 2 )$$

4. The circuit board according to claim 1, wherein
the groove portion extends from the distal end portion of the wall-frame portion in the height direction toward the substrate side as viewed in the thickness direction of the wall-frame portion, and
the width of the groove portion in the width direction orthogonal to the thickness direction and the height direction is larger on the distal end portion side than on the bottom surface side.

5. The circuit board according to claim 1, wherein the width of the groove portion in the width direction orthogonal to the thickness direction and the height direction is larger on an inner peripheral side than on an outer peripheral side as viewed in the height direction.

6. The circuit board according to claim 1, wherein a recess recessed toward an outer peripheral side from an inner peripheral surface of the wall-frame portion is located at a corner portion where a pair of the wall-frame portions are connected to each other as viewed in the height direction.

7. The circuit board according to claim 1, wherein an edge portion of the groove portion is rounded.

8. The circuit board according to claim 1, wherein a dimension of a short side of an inner peripheral surface inside the wall is 8 μm or more, and a dimension of a long side of the inner peripheral surface is 68 μm or less.

9. A method for manufacturing a mounting board, the method comprising mounting an electronic component on the circuit board according to claim 1 to manufacture a mounting board, wherein
a filling material is disposed on the substrate, the electronic component is disposed, and then the electronic component is bonded to the terminal by using a pressurization reflow device.
